(19) United States
(12) Patent Application Publication
(10) Pub. No.: US 2025/0301869 A1
(43) Pub. Date: Sep. 25, 2025

(54) Display Apparatus

(71) Applicant: LG Display Co., Ltd., Seoul (KR)

(72) Inventor: Seunghyun Ahn, Seoul (KR)

(21) Appl. No.: 19/020,420

(22) Filed: Jan. 14, 2025

(30) Foreign Application Priority Data
Mar. 19, 2024 (KR) 10-2024-0038091

(51) Int. Cl. H10K 59/131; H10H 29/49; H10H 29/855; H10K 59/80

(52) U.S. Cl. CPC H10K 59/131; H10H 29/49; H10H 29/8552; H10K 59/8792

(57) ABSTRACT

Provided is a display apparatus. The display apparatus includes a substrate including a display area and a non-display area including a first area, a connection wiring on the substrate in the first area, a reinforcing member on the connection wiring in the first area and a blocking layer between the connection wiring and the reinforcing member in the first area.

### CROSS-REFERENCE TO RELATED APPLICATION

This application claims the priority of Republic of Korea Patent Application No. 10-2024-0038091 filed on Mar. 19, 2024, which is hereby incorporated by reference in its entirety.

### BACKGROUND

### Field

The present disclosure relates to a display apparatus.

### Description of the Related Art

With the advancement of technology in modern society, various display apparatuses are being developed to provide information to users. Examples of display apparatuses displaying images may include various types of display apparatuses such as a liquid crystal display apparatus, an organic light emitting display apparatus, and inorganic light emitting display apparatus.

Since an electroluminescent display apparatus displays images using a self-emitting device, it does not require a separate light source and thus may be implemented in thin and diverse forms.

The display apparatus is expanding its range of applications, and research is being conducted on the display apparatus that has a reduced volume and weight while having a large display area.

### SUMMARY

As the display apparatus becomes smaller and smaller, efforts are being made to reduce a bezel area, which is an outer portion of a display area and is a non-display area, in order to increase an effective display screen size in the same area of the display apparatus.

In relation to a flexible display apparatus that may maintain display performance even when the flexible display apparatus is bent by applying a flexible substrate of a flexible material such as plastic, stress may be transmitted to wirings in a bending area, causing cracks. This may increase the malfunction of a display panel in a room temperature or high-temperature environment. Accordingly, the inventors of the present disclosure recognized the problems mentioned above and invented a new display apparatus capable of improving cracks in a bending part of the display apparatus and improving the performance of the display apparatus.

An object to be achieved by the present disclosure is to provide a display apparatus capable of minimizing or at least reducing cracks in a display panel in a bending area and minimizing a short circuit of a wiring.

Another object to be achieved by the present disclosure is to provide a display apparatus with improved reliability.

Objects of the present disclosure are not limited to the above-mentioned objects, and other objects, which are not mentioned above, can be clearly understood by those skilled in the art from the following descriptions.

A display apparatus according to an exemplary embodiment of the present disclosure includes: a substrate including a display area and a non-display area including a first area, a connection wiring on the substrate in the first area, a reinforcing member on the connection wiring in the first area and a blocking layer between the connection wiring and the reinforcing member in the first area.

Other detailed matters of the exemplary embodiments are included in the detailed description and the drawings.

According to an exemplary embodiment of the present disclosure, by applying the blocking layer to the display apparatus, it is possible to minimize or reduce the malfunction of the display apparatus, thereby improving the performance and/or reliability of the display apparatus.

According to an exemplary embodiment of the present disclosure, by improving the lifespan of the display apparatus, it is possible to provide the eco-friendly, low-power display apparatus with reduced power consumption.

According to an exemplary embodiment of the present disclosure, by applying the blocking layer to the display apparatus to minimize or reduce the cracks in the bending area, it is possible to provide the display apparatus capable of minimizing damage to the bending area.

According to an exemplary embodiment of the present disclosure, it is possible to minimize or reduce the breakage of the protective layer by disposing the blocking layer and minimize or reduce the malfunction of the display apparatus by suppressing the short circuit of the signal wiring.

The effects of the present disclosure are not limited to the aforementioned effects, and other effects, which are not mentioned above, will be apparently understood to a person having ordinary skill in the art from the following description.

The objects to be achieved by the present disclosure, the means for achieving the objects, and the effects of the present disclosure described above do not specify essential features of the claims, and, thus, the scope of the claims is not limited to the disclosure of the present disclosure.

### BRIEF DESCRIPTION OF DRAWINGS

The above and other aspects, features and other advantages of the present disclosure will be more clearly understood from the following detailed description taken in conjunction with the accompanying drawings, in which:

FIG. 1 is a diagram illustrating a display apparatus according to an exemplary embodiment of the present disclosure;

FIG. 2 is a plan view of the display apparatus according to an exemplary embodiment of the present disclosure;

FIG. 3 is a diagram illustrating the display apparatus before bent according to an exemplary embodiment of the present disclosure;

FIG. 4 is a diagram illustrating the display apparatus after bent according to an exemplary embodiment of the present disclosure;

FIG. 5 is a cross-sectional view of a display panel taken along wiring I-I′ of FIG. 2 according to an exemplary embodiment of the present disclosure;

FIGS. 6A to 6C are enlarged diagrams of area A of FIG. 3 according to an exemplary embodiment of the present disclosure;

FIG. 7 is a diagram illustrating the display apparatus before bent according to another exemplary embodiment of the present disclosure;

FIG. 8 is an enlarged view of area B of FIG. 7 according to an exemplary embodiment of the present disclosure;

FIG. 9 is a diagram illustrating the display apparatus after bent according to another exemplary embodiment of the present disclosure; and

FIG. 10 is an enlarged view of area C of FIG. 8 according to an exemplary embodiment of the present disclosure.

### DETAILED DESCRIPTION

Advantages and characteristics of the present disclosure and a method of achieving the advantages and characteristics will be clear by referring to exemplary embodiments described below in detail together with the accompanying drawings. However, the present disclosure is not limited to the exemplary embodiments disclosed herein but will be implemented in various forms. The exemplary embodiments are provided by way of example only so that those skilled in the art can fully understand the disclosures of the present disclosure and the scope of the present disclosure.

The shapes, sizes, ratios, angles, numbers, and the like illustrated in the accompanying drawings for describing the exemplary embodiments of the present disclosure are merely examples, and the present disclosure is not limited thereto. Like reference numerals generally denote like elements throughout the specification. Further, in the following description of the present disclosure, a detailed explanation of known related technologies may be omitted to avoid unnecessarily obscuring the subject matter of the present disclosure. The terms such as “including,” “having,” and “comprising” used herein are generally intended to allow other components to be added unless the terms are used with the term “only”. Any references to singular may include plural unless expressly stated otherwise.

Components are interpreted to include an ordinary error range even if not expressly stated.

When the position relation between two parts is described using the terms such as “on”, “above”, “below”, and “next”, one or more parts may be positioned between the two parts unless the terms are used with the term “immediately” or “directly”.

When the relation of a time sequential order is described using the terms such as “after”, “continuously to”, “next to”, and “before”, the order may not be continuous unless the terms are used with the term “immediately” or “directly”.

Although the terms “first”, “second”, and the like are used for describing various components, these components are not confined by these terms. These terms are merely used for distinguishing one component from the other components. Therefore, a first component to be mentioned below may be a second component in a technical concept of the present disclosure.

In describing components of the exemplary embodiment of the present disclosure, terminologies such as first, second, A, B, (a), (b), and the like may be used. These terminologies are used to distinguish a component from the other component, but a nature, an order, or the number of the components is not limited by the terminology. When a component is “linked”, “coupled”, or “connected” to another component, the component may be directly linked or connected to the other component. However, unless specifically stated otherwise, it should be understood that a third component may be interposed between the components which may be indirectly linked or connected.

It should be understood that “at least one” includes all combinations of one or more of associated components. For example, “at least one of first, second, and third components” means that not only a first, second, or third component, but also all combinations of two or more of first, second, and third components are included.

In the present disclosure, a “display apparatus” may include a display apparatus which includes a display panel and a driver for driving the display panel, in a narrow sense, such as a liquid crystal module (LCM), an organic light emitting module (OLED module), and a quantum dot module. Further, the “display apparatus” may further include a set electronic apparatus or a set apparatus (or a set device) which is a complete product or a final product including an LCM, an OLED module, a QD module, etc., such as a notebook computer, a television, or a computer monitor, an automotive display apparatus or equipment display apparatus including another type of vehicle and a mobile electronic apparatus including a smart phone or an electronic pad.

Accordingly, the display apparatus of the present disclosure may include not only a display apparatus itself in a narrow sense such as a LCM, an OLED module, a QD module, etc., but also an applied product or a set apparatus which is a final consumer device including the LCD, the OLED module, the QD module, etc.

Further, in some cases, the LCM, the OLED module, or the QD module which is configured by a display panel and a driver may be represented as “a display apparatus” in a narrow sense and an electronic device as a complete product including the LCM, the OLED module, and the QD module may be represented as a “set apparatus”. For example, the display apparatus in the narrow sense includes a liquid crystal (LCD) display panel, an OLED display panel, or a quantum dot display panel and a source PCB which is a controller for driving the display panel. In contrast, the set apparatus may be a concept further including a set PCB which is a set controller which is electrically connected to the source PCB to control the entire set apparatus.

As a display panel used in the exemplary embodiment of the present disclosure, any type of display panel such as a liquid crystal display panel, an organic light emitting diode (OLED) display panel, a quantum dot (QD) display panel, and an electroluminescent display panel may be used. The display panel of the present exemplary embodiment is not limited to a specific display panel in which a bezel is bent with a flexible substrate for the organic light emitting diode (OLED) display panel and a back plate support structure there below. Further, a display panel used for the display apparatus according to the exemplary embodiment of the present disclosure is not limited to a shape or a size of the display panel.

For example, when the display panel is an OLED display panel, the display panel may include a plurality of gate lines, data lines, and pixels formed at intersecting areas of the gate lines and/or data lines. Further, the display panel may be configured to include an array including a thin film transistor which is an element to selectively apply a voltage to each pixel, a light emitting diode layer on the array, an encapsulation substrate or an encapsulation layer, and the like disposed on the array so as to cover the light emitting diode layer. The encapsulation layer may protect the thin film transistor, the light emitting diode layer, and the like from external impacts and may suppress the permeation of moisture or oxygen into the light emitting diode layer. Further, a layer formed on the array may include an inorganic light emitting layer, for example, a nano-sized material layer quantum dots, or the like.

The features of various embodiments of the present disclosure can be partially or entirely adhered to or combined with each other and can be interlocked and operated in technically various ways, and the embodiments can be carried out independently of or in association with each other.

Hereinafter, the exemplary embodiment of the present disclosure will be described with reference to the accompanying drawings and exemplary embodiments as follows. Scales of components illustrated in the accompanying drawings are different from the real scales for the purpose of description, so that the scales are not limited to those illustrated in the drawings.

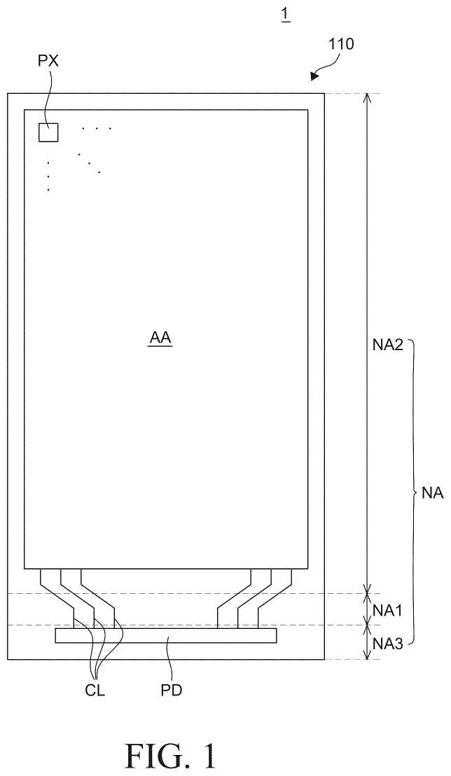

FIG. 1 is a diagram illustrating a display apparatus according to an exemplary embodiment of the present disclosure.

A display apparatus 1 according to an exemplary embodiment of the present disclosure may include a substrate 110. The display apparatus 1 may include a display area AA provided on the substrate 110 and a non-display area NA disposed around the display area AA.

In an exemplary embodiment, the substrate 110 may be made of a plastic material having flexibility to enable bending. For example, the substrate 110 may be made of materials such as polyimide (PI), polyethylene terephthalate (PET), polyethylene naphthalate (PEN), polycarbonate (PC), polyethersulfone (PES), polyarylate (PAR), polysulfone (PSF), and cyclo-olefin copolymer (COS), and the exemplary embodiments of the present disclosure are not limited thereto. For example, glass is not excluded as a material of the substrate 110. In another exemplary embodiment of the present disclosure, the substrate 110 may be made of a semiconductor material such as a silicon wafer.

The display area AA may be an area where a plurality of pixels PXs are disposed and an image is displayed. The plurality of pixels PXs may include a plurality of sub-pixels. Each of the plurality of sub-pixels may be an individual unit that emits light. A light emitting element and a driving circuit may be disposed in each of the plurality of sub-pixels. For example, display elements for displaying images and circuit units for driving the display elements may be disposed in the plurality of sub-pixels. For example, when the display apparatus 1 is an organic light emitting display apparatus, the display element may include organic light emitting diode (OLED), and when the display apparatus 1 is an inorganic light emitting display apparatus, the display element may include micro inorganic light emitting diode (micro-LED). A plurality of pixels PXs may include red sub-pixels, green sub-pixels, blue sub-pixels, white sub-pixels, etc., and the exemplary embodiments of the present disclosure are not limited thereto.

The non-display area NA may be an area where an image is not displayed. The non-display area NA may be an area where various wirings and driving ICs for driving the plurality of pixels PXs disposed in the display area AA are disposed. For example, at least one of a data driver and a gate driver may be disposed in the non-display area NA, but the exemplary embodiments of the present disclosure are not limited thereto.

The non-display area NA may be an area that at least partially encloses the display area AA. For example, the non-display area NA may be around the display area AA. For example, the non-display area NA may be an area extending from the display area AA or may be an area where the plurality of pixels PXs are not disposed, and the exemplary embodiments of the present disclosure are not limited thereto.

The non-display area NA, where the image is not displayed, may further include a first area NA1, which is a bezel area or a bending area where the substrate 110 is bent, and the exemplary embodiments of the present disclosure are not limited thereto.

The pixel PX of the display area AA may include a thin film transistor or a transistor formed of a semiconductor layer. For example, the thin film transistor or the transistor may include an oxide semiconductor material, and the exemplary embodiments of the present disclosure are not limited thereto. For example, the thin film transistor may be a transistor, and the term are not limited thereto.

The first area NA1 may be a bending region where the substrate 110 is bent (curved). The substrate 110 may be kept flat except for the first area NA1.

A pad PD is disposed on one side of the substrate 110 in the non-display area NA, so an external module may be bonded.

The non-display area NA is not an area where an image is displayed, and thus, does not need to be recognized on a top surface of the substrate 110. Therefore, a portion of the non-display area NA of the substrate 110 may be bent to reduce the bezel area while securing an area for the wiring and the driving circuit.

Various wirings may be formed on the substrate 110. The wiring may be formed in the display area AA of the substrate 110, or a plurality of connection wirings CL formed in the non-display area NA may transmit signals by connecting the driving circuit, the gate driver, the data driver, etc., to each other.

The connection wiring CL may be disposed in the first area NA1 which is the bending area. For example, various connection wirings CLs may be disposed in the first area NA1 and connected to the data pads.

The plurality of connection wirings CLs are made of a conductive material and may be made of a conductive material having excellent flexibility to reduce the occurrence of cracks when the substrate 110 is bent. The plurality of connection wirings CLs may be made of a conductive material having excellent flexibility, such as gold (Au), silver (Ag), and aluminum (Al), or may also be made of one of various conductive materials used in the display area AA. The plurality of connection wirings CLs may also be made of molybdenum (Mo), chromium (Cr), titanium (Ti), nickel (Ni), neodymium (Nd), copper (Cu), an alloy of silver (Ag) and magnesium (Mg), etc.

The plurality of connection wirings CLs may be formed of a multilayer structure including various conductive materials. For example, the plurality of connection wirings CLs may be configured as a three-layer structure of titanium (Ti)/aluminum (Al)/titanium (Ti), but is not limited thereto.

The plurality of connection wirings CLs formed in the non-display area NA may be subjected to tensile force when bent. The plurality of connection wirings CLs extending in the same direction as the bending direction on the substrate 110 may be subjected to the greatest tensile force, which may cause cracks or disconnection. For example, instead of forming the plurality of connection wirings CLs to extend in the bending direction, at least some of the plurality of connection wirings CLs disposed including the bending area may be formed to extend in a diagonal direction different from the bending direction, thereby minimizing the tensile force.

The plurality of connection wirings CLs may be formed in various shapes, and may be formed in, for example, a trapezoidal wave shape, a triangular wave shape, a sawtooth wave shape, a sine wave shape, an omega (Ω) shape, a rhombus shape, etc. An exemplary embodiment of the present disclosure is not limited thereto.

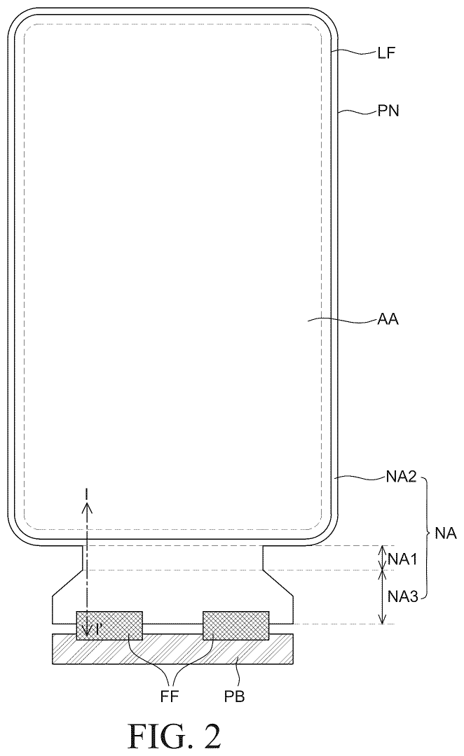

FIG. 2 is a plan view of the display apparatus according to an exemplary embodiment of the present disclosure.

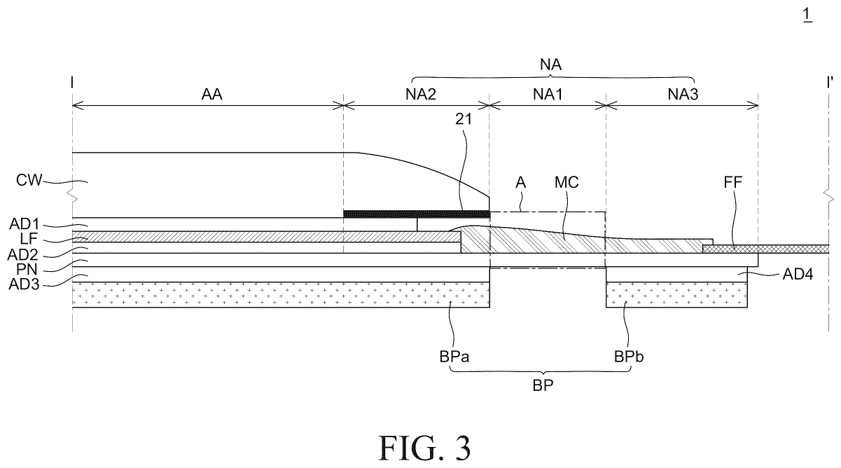

FIG. 3 is a diagram illustrating the display apparatus before bent according to an exemplary embodiment of the present disclosure. FIG. 3 is a cross-sectional view of the display apparatus before bent taken along wiring I-I′ of FIG. 2 according to an exemplary embodiment of the present disclosure.

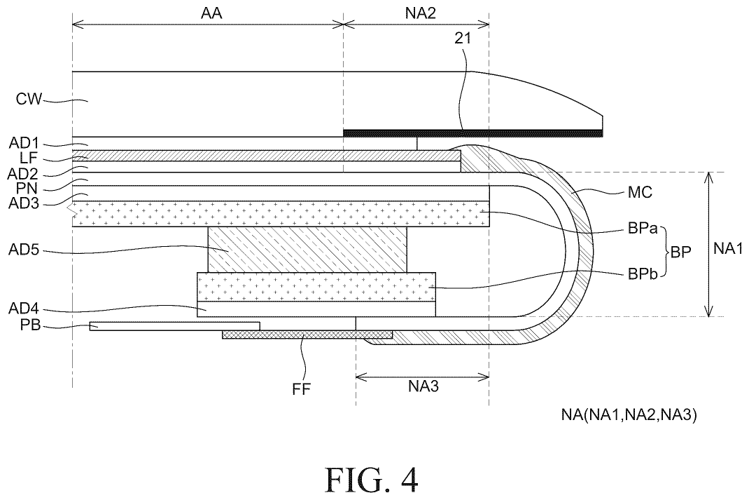

FIG. 4 is a diagram illustrating the display apparatus after bent according to an exemplary embodiment of the present disclosure. FIG. 4 is a cross-sectional view of the display apparatus after bent taken along wiring I-I′ of FIG. 2.

In FIG. 2, a display panel PN, an optical film LF, a driving circuit unit FF, and a circuit board PB among various components of the display apparatus 1 are illustrated.

Referring to FIGS. 2 and 3, the display apparatus 1 may include a cover member CW, a first fixing member AD1, an optical film LF, a second fixing member AD2, a display panel PN, a third fixing member AD3, a support member BP, a fourth fixing member AD4, a reinforcing member MC, a driving circuit unit FF, and a printed circuit board (PCB).

Referring to FIG. 2, the display panel PN may include the display area AA and the non-display area NA enclosing at least a portion of the display area AA.

The display area AA is an area where an image is displayed on the display apparatus 1.

The non-display area NA is an area where an image is not displayed and may be an area extending from the display area AA. The non-display area NA may include the first area NA1, a second area NA2, and a third area NA3.

The first area NA1 may be an area that is bent to minimize or reduce the bezel area. For example, the second area NA2 may be an area that at least partially encloses the display area AA.

The first area NA1 may be an area extending from the second area NA2.

The plurality of connection wirings CLs, which are connected to a plurality of pad electrodes of the third area NA3, may be disposed in the second area NA2. The plurality of connection wirings CL may be, for example, a link wiring.

The plurality of connection wirings CLs may extend from the display area AA to the first area NA1, the second area NA2, and the third area NA3.

The third area NA3 is an area extending from the first area NA1. As the first area NA1 is bent, the third area NA3 may be disposed to face the display area AA and the first area NA1. The third area NA3 may be an area where the plurality of pad electrodes are disposed and may be an area where a plurality of driving circuit units FF are bonded.

The display panel PN may include the substrate 110 and the light emitting element.

In an exemplary embodiment, the substrate 110 is a support member for supporting other components disposed on the substrate of the display apparatus 1 and may be made of an insulating material. For example, the substrate may be made of glass, resin, or the like. In addition, the substrate may be made of a polymer or plastic such as polyimide (PI) or may be made of a material with flexibility.

The light emitting element may be disposed on the substrate. The light emitting element may be defined differently depending on the type of display panel PN. When the display panel PN is, for example, an organic light emitting display panel, the light emitting element may be an organic light emitting diode (OLED). When the display panel PN is, for example, an inorganic light emitting display panel, the light emitting element may be an inorganic light emitting diode or micro-LED. An exemplary embodiment of the present disclosure is not limited thereto.

A driving transistor for driving the light emitting element may be disposed between the substrate and the light emitting element. The driving transistor may be disposed in each of the plurality of pixels PXs. The driving transistor may include, for example, a gate electrode, an active layer, a source electrode, and a drain electrode. In addition, the driving transistor may further include a gate insulating layer for insulating the gate electrode and the active layer, and further include an interlayer insulating layer for insulating the gate electrode, the source electrode, and the drain electrode.

Referring to FIGS. 2 to 4, the plurality of driving circuit units FF may be disposed at one end of the display apparatus 1. For example, the plurality of driving circuit units FF may be disposed in the third area NA3. The plurality of driving circuit unit FFs may be a film for supplying signals to a plurality of sub-pixels of the display area AA by disposing various components, such as a driving IC, on a base film with flexibility. The plurality of driving circuit unit FFs may be disposed at one end of the non-display area NA of the display apparatus 1 to supply a data voltage, etc., to a plurality of sub-pixels SPs of the display area AA.

The drivers such as the gate driver and the data driver may be disposed in the plurality of driving circuit unit FFs. According to the method of mounting a driver, the driver may be disposed by methods such as a chip on glass (COG), chip on film (COF), and tape carrier package (TCP), but the mounting method is not limited thereto. The shapes and number of the plurality of driving circuit unit FFs illustrated in FIG. 2 are merely exemplary, and the shapes and number of the driving circuit unit FFs may be variously changed as needed and are not limited thereto.

Referring to FIG. 2, the circuit board PB may be connected to the plurality of driving circuit unit FFs. For example, the circuit board PB may be a printed circuit board (PCB). The circuit board PB may be connected to the plurality of driving circuit units FFs. The circuit board PB is a component that supplies signals to the driving IC.

Various components for supplying various driving signals, such as the driving signals and the data voltage, to the driving IC may be disposed on the circuit board PB. The exemplary embodiment of the present disclosure is not limited thereto.

Referring to FIG. 4, the third fixing member AD3 may be disposed between a display panel PN and a support member BP. A third fixing member AD3 may fix the display panel PN and a first support member BPa of the support member BP. The third fixing member AD3 is a material formed of materials such as a pressure sensitive adhesive (PSA), an optical clear adhesive (OCA), or an optical clear resin (OCR) and a material including the materials, but is not limited thereto.

A fourth fixing member AD4 may be disposed between the bent display panel PN and a second support member BPb. The fourth fixing member AD4 may fix a second support member BPb (BP). The fourth fixing member AD4 is a material formed of materials such as a pressure sensitive adhesive (PSA), an optical clear adhesive (OCA), or an optical clear resin (OCR) and a material including the materials, but is not limited thereto.

A fifth fixing member AD5 may be disposed to fix the support member BP by bonding the support member BP, which is disposed to be spaced apart from each other before the display apparatus 1 is bent, after the display apparatus 1 is bent. In FIG. 4, the fifth fixing member AD5 is illustrated as being bent while being disposed and bonded under the first support member BPa, but the exemplary embodiments are not limited thereto. The fifth fixing member AD5 is a material formed of materials such as a pressure sensitive adhesive (PSA), an optical clear adhesive (OCA), or an optical clear resin (OCR) and a material including the materials, but is not limited thereto.

Referring to FIG. 4, for example, the cover member CW may be formed of a transparent plastic material that may transmit an image and a cover glass of a transparent glass material, but is not limited thereto.

For example, a light-shielding pattern 21 may be formed on four edges of the cover member CW. For example, the light-shielding pattern 21 may be formed on an edge of a rear surface of the cover member CW. In an exemplary embodiment, the light-shielding pattern 21 may be formed to overlap a portion of the first fixing member AD1, the optical film LF, and the display panel 1 under the light-shielding patter 21.

For example, the light-shielding pattern 21 may include a black material, such as black ink or black pigment with low transmittance, to define a border of the display area AA.

In an exemplary embodiment, the light-shielding pattern 21 may be made of chromium (Cr) and graphite.

The optical film LF may suppress external light from being reflected to improve outdoor visibility and contrast ratio for an image displayed on the display panel PN. The optical film LF may be, for example, a polarizing plate (POL) composed of a polarizer and a protective film protecting the polarizer and may be formed by coating a polarizing material for flexibility. The exemplary embodiment of the present disclosure is not limited thereto.

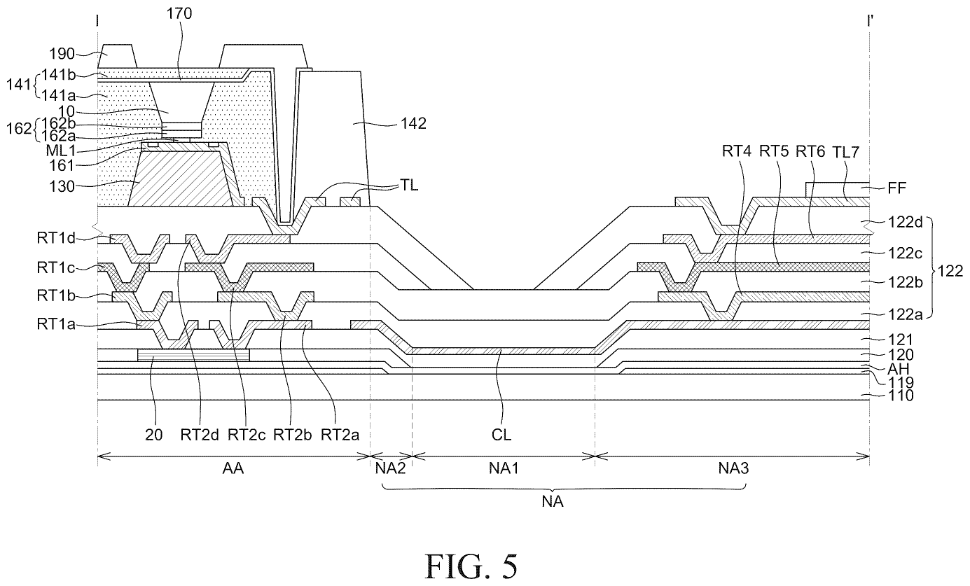

The driving circuit unit FF may be disposed in the form of a chip on plastic (COP) or a chip on film (COF) mounted on the substrate 110, but is not limited thereto. FIG. 5 is a cross-sectional view of the display panel taken along wiring I-I′ of FIG. 2.

Referring to an exemplary embodiment of the present disclosure according to FIG. 5, the display panel may include a plurality of first electrodes 161 disposed on the substrate 110, a plurality of light emitting elements 10 disposed on the plurality of first electrodes 161, a first optical layer 141, and a second electrode 170 disposed on the plurality of light emitting elements 10.

A buffer layer 119 may be disposed on the substrate 110. The buffer layer 119 may be, for example, an inorganic material or an inorganic layer. The buffer layer 119 may be used by laminating inorganic insulating materials, such as silicon nitride (SiNx) or silicon oxide (SiO2), in a multilayer, and may be used by laminating organic insulating materials and inorganic insulating materials in a multilayer. The exemplary embodiment of the present disclosure is not limited thereto. For example, the buffer layer 119 may be disposed in the second area NA2 and/or the third area NA3, excluding the first area NA1 which is a bending area for bending.

An insulating layer AH may be disposed on the substrate 110. For example, the insulating layer AH may be an adhesive layer. There may be an area where the insulating layer AH is removed in the non-display area NA or the first area NA1. For example, this may be because there is a risk of damage or breakage to the component or layer in the first area NA1 as there are more components or layers in the first area NA1. The insulating layer AH may be selected from any one of, for example, an adhesive polymer, an epoxy resin, a UV resin, polyimide series, acrylate series, urethane series, and polydimethylsiloxane (PDMS), but is not limited thereto.

In the display area AA, a pixel driving circuit 20 implemented as a driving driver may be disposed on the insulating layer AH.

For example, the pixel driving circuit 20 may be disposed on the substrate 110 in the display area AA. The pixel driving circuit 20 may include a plurality of thin film transistors using an amorphous silicon semiconductor, a polycrystalline silicon semiconductor, or an oxide semiconductor.

The pixel driving circuit 20 may include at least one driving thin film transistor, at least one switching thin film transistor, and at least one storage capacitor. When the pixel driving circuit 20 includes the plurality of thin film transistors, they may be formed on the substrate 110 by a process of manufacturing a thin film transistor (TFT). In the exemplary embodiment, the pixel driving circuit 20 may be a concept that collectively refers to a plurality of thin film transistors that are electrically connected to the light emitting element 10.

The pixel driving circuit 20 may be a driving driver manufactured using a process of manufacturing a metal-oxide-silicon field effect transistor (MOSFET) on a single crystal semiconductor substrate. The driving driver may include a plurality of pixel driving circuits to drive a plurality of sub-pixels. When the pixel driving circuit 20 is implemented as the driving driver, after the insulating layer AH is disposed on the substrate 110, the driving driver may be mounted on the insulating layer AH by a transfer process. The pixel driving circuit 20 may be a micro driver or a microchip, and the exemplary embodiments of the present disclosure are not limited thereto.

An overcoat layer 120 may be formed on the insulating layer AH to protect the pixel driving circuit 20. The overcoat layer 120 may cover at least a portion or the entirety of a side surface of the pixel driving circuit 20 and may cover a portion of the top surface of the pixel driving circuit 20. For example, the overcoat layer 120 may cover the entirety of the substrate 110 and may also cover a portion or the entirety of the third area NA3. The overcoat layer 120 may be made of an organic insulating material, for example, a photosensitive photo acryl or a photosensitive polyimide, but is not limited thereto.

The buffer layer 121 may be disposed on the overcoat layer 120 and/or the pixel driving circuit 20. When the overcoat layer 120 covers only a portion of the third area NA3, the side surface of the overcoat layer 120 may be covered by the buffer layer 121.

The protective layer 122 may be disposed on the buffer layer 121. The protective layer 122 may be, for example, an organic material. The exemplary embodiment of the present disclosure is not limited thereto. A 1a-th wiring RT1a, a 2a-th wiring RT2a, and a plurality of connection wirings CLs may be disposed on the buffer layer 121.

For example, the protective layer 122 may be an insulating layer and/or an organic layer. The exemplary embodiment of the present disclosure is not limited thereto. In an exemplary embodiment, the protective layer 122 may include a first protective layer 122a, a second protective layer 122b thereon, third protective layer 122c thereon, and/or a fourth protective layer 122d thereon.

The first protective layer 122a may be disposed on the 1a-th wiring RT1a, the 2a-th wiring RT2a, and the plurality of connection wirings CLs.

A 1b-th wiring RT1b, a 2b-th wiring RT2b, and a fourth wiring RT4 may be disposed on the first protective layer 122a.

The second protective layer 122b may be disposed on the 1b-th wiring RT1b, the 2b-th wiring RT2b, and the fourth wiring RT4.

A 1c-th wiring RT1c, a 2c-th wiring RT2c, and a fifth wiring RT5 may be disposed on the second protective layer 122b.

The third protective layer 122c may be disposed on the 1c-th wiring RT1c, the 2c-th wiring RT2c, and the fifth wiring RT5.

A 1d-th wiring RT1d, a 2d-th wiring RT2d, and a sixth wiring RT6 may be disposed on the third protective layer 122b.

The fourth protective layer 122d may be disposed on the 1d-th wiring RT1d, the 2d-th wiring RT2d, and the sixth wiring RT6. The more protective layers there are in the first area NA1, the more defects may occur in which the protective layer is damaged during bending. The fourth protective layer 122d may not be disposed in at least some areas of the first area NA1. n (0<n<5, and n is an integer) protective layers may be disposed in the first area NA1.

In an exemplary embodiment, the 1a-th wiring RT1a may be the first wiring.

Referring to FIG. 5, the 1a-th wiring RT1a is included on the substrate in the display area AA, and the connection wiring CL of the first area NA1 may be the same material as the first wiring of the display area AA.

In order to facilitate the bending in the bending area, the buffer layer 119, which is an inorganic material, may not be disposed in the first area NA1. Accordingly, the distance from the substrate 110 to the connection wiring CL may be different from the distance from the substrate 110 to the 1a-th wiring RT1a. For example, the distance from the substrate 110 to the connection wiring CL may be shorter than the distance from the substrate 110 to the 1a-th wiring RT1a.

A plurality of signal wirings TLs and a seventh wiring TL7 may be disposed on the fourth protective layer 122d. For example, the plurality of signal wirings TLs and the seventh wiring TL7 may be disposed on the same layer. Disposing the plurality of signal wirings TLs and the seventh wiring TL7 on the same layer may mean that they are formed entirely on one layer and then formed to be separated by a patterning process or the like. However, it is not necessarily limited thereto, and a plurality of wirings or electrodes may be defined as disposed on the same layer as long as the plurality of wirings or electrodes are formed on the same layer although their heights may be different.

The 1a-th wiring RT1a, the 1b-th wiring RT1b, the 1c-th wiring RT1c, the 1d-th wiring RT1d, and the plurality of signal wirings TL may be electrically connected through contact holes penetrating through the protective layer on which each of these are disposed.

The 2a-th wiring RT2a, the 2b-th wiring RT2b, the 2c-th wiring RT2c, and the 2d-th wiring RT2d may be electrically connected through the contact holes penetrating through the protective layer on which each of these are disposed.

An anode voltage supplied from the pixel driving circuit 20 may be supplied to the light emitting element 10 through the 1a-th wiring RT1a, the 1b-th wiring RT1b, the 1c-th wiring RT1c, the 1d-th wiring RT1d, the plurality of signal wirings TL, and the first electrode 161.

A cathode voltage supplied from the pixel driving circuit 20 may be supplied to the light emitting element 10 through the 2a-th wiring RT2a, the 2b-th wiring RT2b, the 2c-th wiring RT2c, the 2d-th wiring RT2d, the plurality of signal wirings TL, and the second electrode 170.

The wirings listed above are examples, and each wiring may include a plurality of connection wirings or a plurality of wiring patterns disposed in different layers having one or more protective layers interposed therebetween. The wiring patterns disposed in different layers may be electrically connected through the contact holes penetrating through the protective layer.

The plurality of connection wirings CLs is disposed on the buffer layer 121. The plurality of connection wirings CLs may extend from the display area AA to the third area NA3. The plurality of connection wirings CLs may be a third wiring.

The fourth wiring RT4 is disposed on the first protective layer 122a and may extend to the third area NA3.

The fifth wiring RT5 is disposed on the second protective layer 122b and may extend to the third area NA3.

The sixth wiring RT6 is disposed on the third protective layer 122c and may extend to the third area NA3.

The seventh wiring RT5 is disposed on the fourth protective layer 122b and may extend to the third area NA3.

For example, a signal from the driving circuit unit FF, such as the chip on film (COF) connected to the circuit board PB, may be transmitted to the pixel driving circuit 20 disposed in the display area AA through the seventh wiring TL7, the sixth wiring RT6, the fifth wiring RT5, the fourth wiring RT4, and the plurality of connection wirings CLs.

A plurality of banks 130 may be disposed on the protective layer 122. At least one light emitting element 10 may be disposed on each bank 130. For example, a first light emitting element may be disposed on a first bank, a second light emitting element may be disposed on a second bank, and a third light emitting element may be disposed on a third bank.

The first electrode 161 may be disposed on the bank 130. For example, a first metal layer ML1 may be disposed in an area overlapping the first electrode 161 and the light emitting element 10. For example, the first metal layer ML1 may not be disposed in an area other than the area overlapping the light emitting element 10. The first metal layer ML1 may not be disposed in the third area NA3.

A solder pattern 162 may be disposed on the first electrode 161. The solder pattern 162 may be made of, but is not limited to, indium (In), tin (Sn), or an alloy thereof. The solder pattern 162 may include a first part 162a and a second part 162b.

The first part 162a may include indium (In), and the second part 162b may include gold (Au). The first part 162a and the second part 162b may be bonded by pressure when the light emitting element 10 is transferred, and then eutectically bonded by being subjected to heat. When the second part 162b is subjected to pressure, a portion of the second part 162b may cover at least a portion or the entirety of a side surface of the first part 162a. For example, the contact area between the first part 162a and the second part 162b may increase, thereby increasing the bonding strength and improving the electrical signal transmission.

The plurality of light emitting elements 10 may be mounted on the solder pattern 162, respectively.

For example, the first optical layer 141 may include a 1-1-th optical layer 141a and a 1-2-th optical layer 141b.

The first optical layer 141 may include an organic insulating material in which fine metal particles, such as titanium dioxide particles, are dispersed. Light emitted from the plurality of light emitting elements 10 may be scattered by the fine metal particles dispersed in the first optical layer 141 and emitted to the outside.

The 1-1-th optical layer 141a may be disposed on the plurality of light emitting elements 10 and the bank 130. For example, the 1-1-th optical layer 141a may cover between the plurality of light emitting elements 10 and between the plurality of banks 130. The planar disposition of the 1-1-th optical layer 141a may be the same as the planar disposition of the first optical layer 141.

The second electrode 170 may be disposed on the plurality of light emitting elements 10. The second electrode 170 may be connected to a pixel PXL. The second electrode 170 may be commonly connected to a sub-pixel.

The 1-2-th optical layer 141b may overlap the 1-1-th optical layer 141a on the second electrode 170. The 1-2-th optical layer 141b may be disposed under the second electrode 170 to increase the amount of light emitted toward the front.

The second optical layer 142 may be an organic insulating material enclosing the first optical layer 141. The second optical layer 142 may be disposed on the protective layer 122 together with the first optical layer 141. The first optical layer 141 may be disposed on the display area AA.

The second optical layer 142 may be an organic insulating material enclosing the first optical layer 141. The second optical layer 142 may be disposed on the insulating layer 122 together with the first optical layer 141. The first optical layer 141 and the second optical layer 142 may include the same material (e.g., siloxane). For example, the first optical layer 141 may be a siloxane including titanium oxide (TiOx), and the second optical layer 142 may be a siloxane not including titanium oxide (TiOx). However, this is not necessarily limited thereto, and the first optical layer 141 and the second optical layer 142 may be made of the same material or different materials.

A black matrix 190 may be disposed on the 1-2-th optical layer 141, the second electrode 170, and the second optical layer 142. The black matrix 190 may be disposed on the 1-2-th optical layer 141 and the second electrode 170. A transmission hole through which light emitted from the light emitting element 10 is emitted to the outside may be formed between the patterns of the black matrix 190.

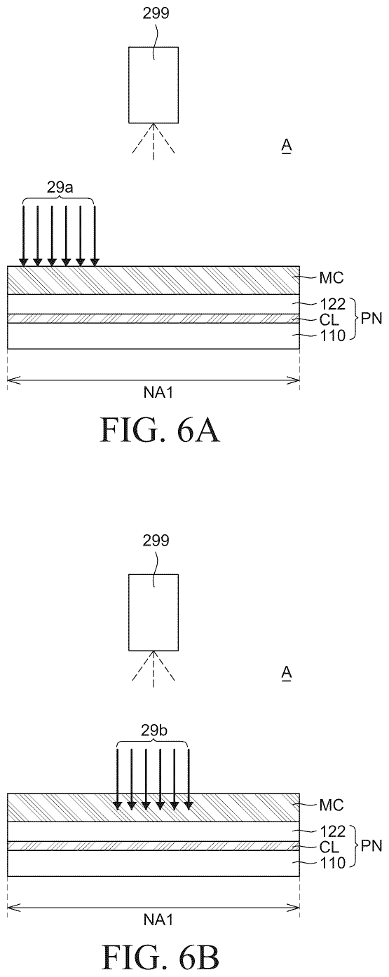

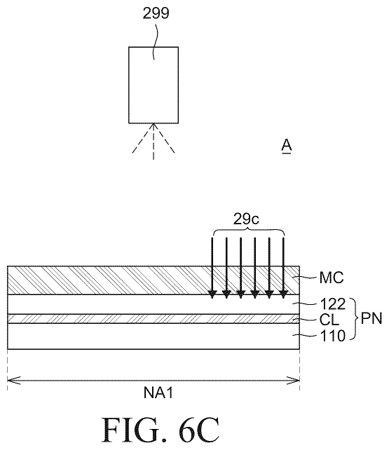

FIGS. 6A to 6C are enlarged diagrams of area A of FIG. 3 according to one embodiment of the present disclosure.

Specifically, FIGS. 6A and 6C are views for describing a process of manufacturing the reinforcing member MC according to an exemplary embodiment.

Referring to FIGS. 3, 4, and 6A to 6C, the area A may be the first area NA1, for example, the bending area. The first area NA1 may include the reinforcing member MC on the display panel PN.

For example, the reinforcing member MC may be a resin, and a curing process may be required.

The reinforcing member MC may include a resin.

The display panel PN may include the plurality of connection wirings CLs on the substrate 110, and the protective layer 122 on the plurality of connection wirings CLs. The protective layer 122 may be, for example, an organic material.

The reinforcing member MC may be disposed on the display panel PN in the first area NA1 to reinforce the bending. For example, the reinforcing member MC may include a micro coating layer. The micro coating layer (MCL) may be a micro cover layer (MCL).

The reinforcing member MC may cover the display panel PN of the first area NA1 and may extend to cover a portion of the third area NA3 of the display panel PN that comes into contact with the first area NA1.

The reinforcing member MC may include a resin, and may include, but is not limited to, an ultraviolet (UV) curable acrylic resin. For example, the reinforcing member MC may be formed of a cured product of a resin that has undergone a curing process after coating the resin. When the resin is used as an ultraviolet curable resin, the ultraviolet curing can be performed.

The reinforcing member MC may be disposed on the outside of the display panel PN to cover various signal wirings of the display panel PN. The reinforcing member MC may suppress moisture from penetrating into the signal connection wiring CL while protecting the signal wirings from external impact.

The reinforcing member MC may supplement the rigidity of the display panel PN in the bending area where the support member is removed by being disposed on the outside of the display panel PN in the first area NA1.

Referring to FIGS. 6A to 6C, the reinforcing member MC on the display panel PN may be cured using a curing device 299. In an exemplary embodiment, the reinforcing member MC may be cured by an ultraviolet (UV) light curing process. Depending on the wavelength range, the ultraviolet (UV) may include short-wavelength UV-C 29a, medium-wavelength UV-B 29b, and long-wavelength UV-A 29c.

Referring to FIGS. 6A, the wavelength range of the short-wavelength UV-C 29a is about 200 nm to 280 nm, and the surface of the reinforcing member MC may be cured.

Referring to FIG. 6B, the wavelength range of the medium-wavelength UV-B 29b is about 280 nm to 315 nm, and a central portion of the reinforcing member MC may be cured.

Referring to FIG. 6C, the wavelength range of the long-wavelength UV-A 29c is about 315 nm to 380 nm, and may harden or brittlely deform the surface of the display panel PN, for example, the surface of the protective layer 122, by passing through the reinforcing member MC. Accordingly, cracks may occur in a plurality of connection wirings CLs in the first area NA1, which is the bending area, thereby causing the malfunction of the display apparatus.

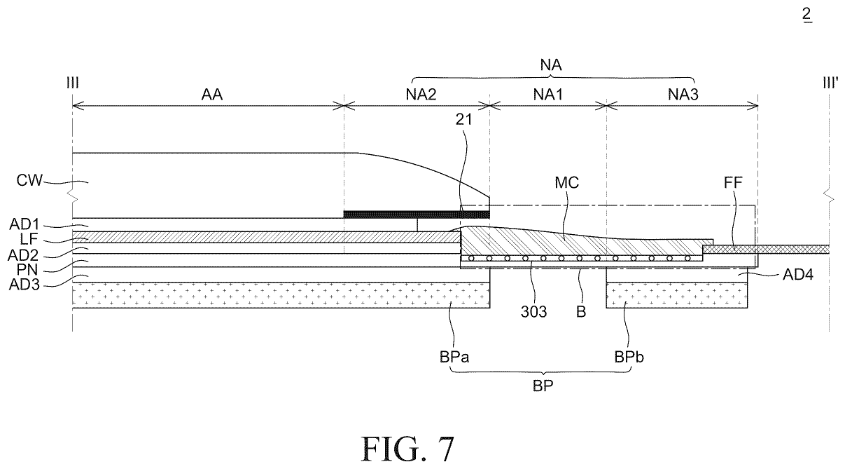

FIG. 7 is a diagram illustrating the display apparatus before bent according to another exemplary embodiment of the present disclosure.

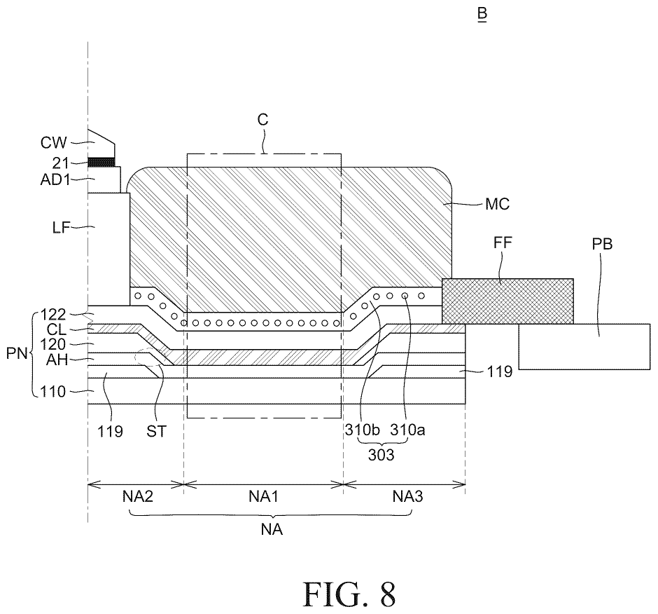

FIG. 8 is an enlarged view of area B of FIG. 7 according to one embodiment.

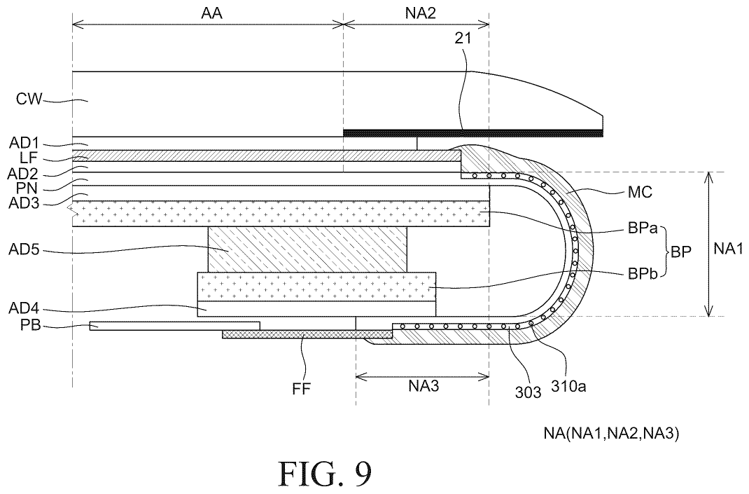

FIG. 9 is a diagram illustrating the display apparatus after bent according to another exemplary embodiment of the present disclosure.

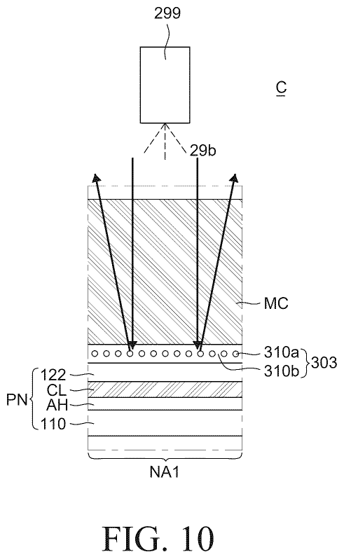

FIG. 10 is an enlarged view of area C of FIG. 8 according to one embodiment.

A display apparatus 2 of FIGS. 7 to 9 may be substantially the same as the display apparatus 1 of FIGS. 1 to 4 except for the blocking layer 303, and therefore, descriptions of overlapping contents may be omitted or simplified.

Referring to FIGS. 7 to 9, the display apparatus 2 may include a cover member CW, a first fixing member AD1, an optical film LF, a display panel PN, a reinforcing member MC, a driving circuit unit FF, and a circuit board PB.

Referring to FIGS. 7 to 9, a blocking layer 303 may be disposed on a display panel PN. Referring to FIG. 8, the blocking layer 303 may be disposed between the plurality of connection wirings CLs and the reinforcing member MC in a first area NA1.

The substrate 110 of the display panel PN may include a display area AA and a non-display area NA. The non-display area NA may include the first area NA1, a second area NA2, and a third area NA3.

The non-display area NA may have the plurality of connection wirings CLs on the substrate 110 in the first area NA1, the second area NA2, and the third area NA3.

There may be the reinforcing member MC on the plurality of connection wirings CLs in at least a portion of the first area NA1, the second area NA2 and the third area NA3.

There may be the blocking layer 303 between the plurality of connection wirings CLs and the reinforcing member MC in at least a portion of the first area NA1, the second area NA2 and the third area NA3.

A protective layer 122 may be on the plurality of connection wirings CLs. The protective layer 122 may be, for example, an organic material, an organic insulating material or an organic layer.

For example, the protective layer 122 may include a plurality of layers.

The protective layer 122 may extend from the display area AA and may be on at least a portion of the first area NA1, the second area NA2 and/or the third area NA3.

The protective layer 122 may be disposed obliquely on a step part ST of an insulating layer AH.

For example, the connection wiring CL and/or the blocking layer 303 may be disposed on the step part ST of the insulating layer AH. Accordingly, the blocking layer 303 may include the step part.

The blocking layer 303 may be between the protective layer 122 and the reinforcing member MC.

Referring to FIG. 8, the blocking layer 303 may include a base layer 310b and a plurality of beads 310a. The blocking layer 303 may include the base layer 310b and the plurality of beads 310a dispersed in the base layer 310b.

For example, the blocking layer 303 may block ultraviolet (UV) rays.

In an exemplary embodiment, the blocking layer 303 may have a thickness of 1 μm to 50 μm.

In an exemplary embodiment, the blocking layer 303 may be a film in which a polyvinyl alcohol resin is used as the base layer 310b, and the plurality of beads 310a, which are composite nanoparticles formed of zinc oxide and titanium oxide, are dispersed within the base layer 310b. In an exemplary embodiment, for example, the beads 310a of the blocking layer 303 may be titanium dioxide (TiO2), but are not limited thereto.

The beads 310a of the blocking layer 303 may be nano particles formed of a material including titanium (Ti). For example, a plurality of first particles LSP1 may be particles having a size of nanometers (nm) formed through a sol-gel method, but are not limited thereto.

The first area NA1 may be an area where the substrate is bent. The blocking layer 303 may overlap the reinforcing member MC in the first area NA1. The blocking layer 303 and the reinforcing member MC may be different. For example, the reinforcing member MC may be a resin. For example, the blocking layer 303 may include the base layer 310b and/or the plurality of beads 310a.

For example, the base layer 310b may be an adhesive material. The base layer 310b may be an acrylic adhesive. The exemplary embodiment of the present disclosure is not limited thereto.

For example, the base layer 310b of the blocking layer 303 may be a low modulus material having a low modulus since it is disposed including the first area NA1 which is the bending area.

For example, as described in FIGS. 6A to 7, for example, when the process of bending the display panel PN while the surface of the protective layer 122 is hardened is performed, the propagation of cracks in the protective layer 122 that may occur may cause the disconnection of the plurality of connection wirings CLs.

Referring to FIG. 10, in the process of curing the reinforcing member MC on the display panel PN in the first area NA1 which is the bending area, the bead 310a of the blocking layer 303 may physically block the long-wavelength UV-A 29c of the curing device 299. Accordingly, the breakage or cracking of the protective layer 122 of the display panel PN may be minimized or reduced. Accordingly, the cracks of the connection wiring CL may be minimized or reduced, thereby minimizing or at least reducing the malfunction.

Referring to FIG. 8, the driving circuit unit FF is disposed in the third area NA3, and the plurality of connection wirings CLs and the driving circuit unit FF are connected, and the blocking layer 303 may not overlap the driving circuit unit FF. Since the blocking layer 303 may suppress damage to the plurality of connection wirings CLs due to the ultraviolet (UV) curing of the reinforcing member MC, the blocking layer 303 may be disposed between the reinforcing member MC and the connection wiring CL. In an exemplary embodiment, the plurality of connection wirings CLs and the driving circuit unit FF are connected, so the blocking layer 303 and the driving circuit unit FF, such as a chip-on-film (COF), may not overlap.

The blocking layer 303 may overlap the first area NA1 between the second area NA2 and the third area NA3. The blocking layer 303 may overlap at least a portion of the second area NA2 and/or at least a portion of the third area NA3.

For example, the diameter of the plurality of beads 310a may be 20 nm or less. The exemplary embodiment of the present disclosure is not limited thereto. By minimizing the diameter of the plurality of beads 310a, the surface area may increase, thereby improving the ultraviolet (UV) blocking effect.

The thickness of the blocking layer 303 may be thinner than the thickness of the reinforcing member MC.

For example, the thickness of the blocking layer 303 may be a thin film of 1 μm or less.

For example, a weight percentage of the plurality of beads 310a may be 5 wt %. The exemplary embodiment of the present disclosure is not limited thereto.

The blocking layer 303 is disposed on the connection wiring CL and under the reinforcing member MC. As a result, since the connection wiring CL of the display panel PN is hardened according to the process of curing the reinforcing member MC, it is possible to minimize or reduce the cracks of the first area NA1 that is bent. By minimizing the cracks of the bending area by the blocking layer 303, it is possible to improve the malfunction.

For example, a buffer layer 119 including the inorganic material may be included in the display area AA and/or the third area NA3. The buffer layer 119 may not be disposed in the first area NA1 which is the bending area. An opening area of the buffer layer 119 may be included in the first area NA1.

Referring to FIG. 8, in the second area NA2 extending from the display area AA, an optical film LF may be disposed on the display panel PN, a first fixing member AD1 may be disposed on the optical film LF, a light-shielding pattern 21 may be disposed on the first fixing member AD1, and a cover member CW may be disposed on the light-shielding pattern 21.

For example, the display panel PN in the second area NA2 may include the buffer layer 119 on the substrate 110, the insulating layer AH on the buffer layer 119, an overcoat layer 120 on the insulating layer AH, the connection wiring CL on the overcoat layer 120, and the protective layer 122 on the connection wiring CL.

For example, an area adjacent to the display area AA in at least a portion of the second area NA2 may include the first fixing member AD1 on the optical film LF on the display panel PN and the cover member CW on the first fixing member AD1.

For example, an area adjacent to the first area NA1 in at least a portion of the second area NA2 may include the blocking layer 303 on the display panel PN and the reinforcing member MC on the blocking layer 303.

For example, the display panel PN in the first area NA1 may exclude the buffer layer 119 which is the inorganic material. The display panel PN in the first area NA1 may include the insulating layer AH on the substrate 110, the overcoat layer 120 on the insulating layer AH, the connection wiring CL on the overcoat layer 120, and the protective layer 122 on the connection wiring CL.

In the first area NA1, the blocking layer 303 may be disposed on the display panel PN, and the reinforcing member MC may be disposed on the blocking layer 303.

Referring to FIG. 8, in an exemplary embodiment, the display panel PN in the first area NA1, which is the bending area, may exclude the buffer layer 119 which is the inorganic material. Accordingly, the substrate 110 and the insulating layer AH disposed between the plurality of connection wirings CLs are included, and the insulating layer AH may have a step part.

By designing a neutral surface in the plurality of connection windings CLs during bending the display panel PN, the stress of the connection winding CL can be minimized or reduced during bending.

The reinforcing member MC may control the neutral plane of the first area NA1 which is the bending area.

As described above, the neutral plane may mean a virtual plane to which a stress is not applied since the compressive force and the tensile force applied to the structure are offset from each other when the structure is bent. When two or more structures are laminated, the virtual neutral plane may be formed between the structures. When the entire structure is bent in one direction, the structures disposed in the bending direction based on the neutral plane are compressed by the bending, and thus are subjected to the compressive force. On the contrary, the structures disposed in the opposite direction to the bending direction based on the neutral plane are stretched by the bending, and thus, are subjected to the tensile force. Since the structures are more vulnerable when subjected to the tensile force among the same compressive force and tensile force, the probability of cracks occurring when subjected to the tensile force is higher.

The substrate of the display panel PN, which is disposed below the neutral plane, is compressed and thus, may be subjected to the compressive force, and the circuit wirings, which are disposed above the neutral plane, may be subjected to the tensile force. Cracks may occur due to the tensile force. Therefore, in order to minimize or reduce the tensile force applied to the circuit wiring, the circuit wiring may be disposed above the neutral plane.

By disposing the reinforcing member MC in the bending area, the neutral plane may be raised upward. The circuit wiring may be disposed at the same position as the neutral plane or disposed higher than the neutral plane, so it does not subjected to the stress or is subjected to the compressive force during bending, thereby suppressing the occurrence of cracks.

For example, the height of the display panel PN in the display area AA may be different from that of the display panel PN in the first area NA1.

The insulating layer AH may be disposed in the display area AA, the first area NA1, the second area NA2, and/or the third area NA3. The step part of the insulating layer AH may be disposed between the first area NA1 and the third area NA3 and disposed to correspond to a boundary between the second area NA2 and the third area NA3.

Referring to FIG. 8, the protective layer 122 protecting the connection wiring CL may be disposed on the plurality of connection wirings CLs. The protective layer 122 may be made of the same material as the protective layer 122 in the display area AA.

The display apparatus according to the exemplary embodiment of the present disclosure may be applied to a mobile device, a video phone, a smart watch, a watch phone, a wearable apparatus, a foldable apparatus, a rollable apparatus, a bendable apparatus, a flexible apparatus, a curved apparatus, a sliding apparatus, a variable apparatus, an electronic notebook, an electronic book, a portable multimedia player (PMP), a personal digital assistant (PDA), an MP3 player, a mobile medical apparatus, a desktop PC, a laptop PC, a netbook computer, a workstation, a navigation system, a vehicle navigation system, a vehicle display apparatus, a vehicle apparatus, a theater apparatus, a theater display apparatus, a television, a wallpaper apparatus, a signage apparatus, a game apparatus, a notebook, a monitor, a camera, a camcorder, home appliances, etc. Further, the display apparatus of the present disclosure may be applied to an organic light emitting lighting device or an inorganic light emitting lighting device.

The exemplary embodiments of the present disclosure can also be described as follows:

According to an aspect of the present disclosure, there is provided a display apparatus. The display apparatus includes a substrate including a display area and a non-display area including a first area, a connection wiring on the substrate in the first area, a reinforcing member on the connection wiring in the first area and a blocking layer between the connection wiring and the reinforcing member in the first area.

The display apparatus may further include a protective layer on the connection wiring. The blocking layer may be between the protective layer and the reinforcing member.

The first area may be an area where the substrate is bent. The blocking layer may overlap the reinforcing member and may be different from the reinforcing member.

The non-display area may further include a second area. The second area may enclose at least a portion of the display area. The connection wiring may extend from the display area to the second area and the first area.

The non-display area may further include a third area extending from the first area. A driving circuit unit may be disposed in the third area. The connection wiring and the driving circuit unit may be connected. The blocking layer may not overlap the driving circuit unit.

The blocking layer may overlap the first area between the second area and the third area and may overlap at least a portion of the second area and at least a portion of the third area.

The display apparatus may further include an insulating layer disposed between the substrate and the connection wiring. The insulating layer may have a step part.

The insulating layer may be disposed in at least one of the display area, the second area, and the third area.

The step part of the insulating layer may be disposed to correspond between the first area and the third area and between the second area and the third area.

The display apparatus may further include a protective layer on the connection wiring. The protective layer may be an organic material.

The protective layer may be disposed obliquely on the step part of the insulating layer.

The connection wiring and the blocking layer may be disposed on the step part of the insulating layer. The blocking layer may include a step part.

The display apparatus may further include a pixel driving circuit disposed in the display area. The insulating layer may be an adhesive layer. The pixel driving circuit may be disposed on the insulating layer. The pixel driving circuit may be a microchip.

The display apparatus may further include a first wiring on the substrate in the display area. The connection wiring in the first area may be the same material as the first wiring in the display area. A distance from the substrate to the connection wiring may be smaller than a distance from the substrate to the first wiring.

The blocking layer may include a plurality of beads.

The blocking layer may include a base layer and beads dispersed in the base layer.

The blocking layer may include a base layer. The base layer may include an adhesive material.

A diameter of the beads may be 20 nm or less.

A thickness of the blocking layer may be thinner than that of the reinforcing member.

Although the exemplary embodiments of the present disclosure have been described in detail with reference to the accompanying drawings, the present disclosure is not limited thereto and may be embodied in many different forms without departing from the technical concept of the present disclosure. Therefore, the exemplary embodiments of the present disclosure are provided for illustrative purposes only but not intended to limit the technical concept of the present disclosure. The scope of the technical concept of the present disclosure is not limited thereto. Therefore, it should be understood that the above-described exemplary embodiments are illustrative in all aspects and do not limit the present disclosure. All the technical concepts in the equivalent scope of the present disclosure should be construed as falling within the scope of the present disclosure.

What is claimed is:

1. A display apparatus, comprising:
a substrate including a display area and a non-display area including a first area;
a connection wiring on the substrate in the first area;
a reinforcing member on the connection wiring in the first area; and
a blocking layer between the connection wiring and the reinforcing member in the first area.

2. The display apparatus according to claim 1, further comprising:
a protective layer on the connection wiring,
wherein the blocking layer is between the protective layer and the reinforcing member.

3. The display apparatus according to claim 1, wherein the first area is an area where the substrate is bent and the blocking layer overlaps the reinforcing member and is different from the reinforcing member.

4. The display apparatus according to claim 1, wherein the non-display area further includes a second area that encloses at least a portion of the display area and the connection wiring extends from the display area to the second area and further extends to the first area.

5. The display apparatus according to claim 4, wherein the non-display area further includes a third area extending from the first area, and the display apparatus further comprises:
a driving circuit unit in the third area,
wherein the connection wiring and the driving circuit unit are connected and the blocking layer is non-overlapping with the driving circuit unit.

6. The display apparatus according to claim 5, wherein the blocking layer overlaps the first area between the second area and the third area and the blocking layer overlaps at least a portion of the second area and at least a portion of the third area.

7. The display apparatus according to claim 5, further comprising:
an insulating layer between the substrate and the connection wiring, the insulating layer having a step part.

8. The display apparatus according to claim 7, wherein the insulating layer is in at least one of the display area, the first area, the second area, and the third area.

9. The display apparatus according to claim 7, wherein the step part of the insulating layer is disposed to correspond a boundary between the first area and the third area and a boundary between the second area and the third area.

10. The display apparatus according to claim 7, further comprising:
a protective layer on the connection wiring, the protective layer including an organic material.

11. The display apparatus according to claim 10, wherein the protective layer is disposed obliquely on the step part of the insulating layer.

12. The display apparatus according to claim 10, wherein the connection wiring and the blocking layer are on the step part of the insulating layer and the blocking layer includes a step part.

13. The display apparatus according to claim 7, further comprising:
a pixel driving circuit in the display area,
wherein the insulating layer is an adhesive layer, the pixel driving circuit is on the insulating layer, and the pixel driving circuit is a microchip.

14. The display apparatus according to claim 1, further comprising:
a first wiring on the substrate in the display area,
wherein the connection wiring in the first area is a same material as the first wiring in the display area and a distance from the substrate to the connection wiring is smaller than a distance from the substrate to the first wiring.

15. The display apparatus according to claim 1, wherein the blocking layer includes a plurality of beads.

16. The display apparatus according to claim 1, wherein the blocking layer includes a base layer and beads dispersed in the base layer.

17. The display apparatus according to claim 1, wherein the blocking layer includes a base layer and the base layer includes an adhesive material.

18. The display apparatus according to claim 16, wherein a diameter of the beads is 20 nm or less.

19. The display apparatus according to claim 1, wherein a thickness of the blocking layer is thinner than a thickness of the reinforcing member.

20. The display apparatus according to claim 1, wherein the reinforcing member is a curable resin.

21. The display apparatus according to claim 7, further comprising:
a buffer layer disposed between the substrate and the insulating layer,
wherein the buffer layer is not disposed in the first area.
